(19) United States
(12) Patent Application Publication
(10) Pub. No.: US 2023/0337468 A1
(43) Pub. Date: Oct. 19, 2023

(54) DISPLAY DEVICE

(71) Applicant: Samsung Display Co., Ltd., Yongin-si (KR)

(72) Inventor: KEUNWOO KIM, Seongnam-si (KR)

(21) Appl. No.: 18/076,743

(22) Filed: Dec. 7, 2022

(30) Foreign Application Priority Data
Apr. 18, 2022 (KR) 10-2022-0047578

(51) Int. Cl. H01L 51/00

(52) U.S. Cl. CPC H01L 27/3262; H01L 27/3265; H01L 27/3276

(57) ABSTRACT

A display device includes a light emitting diode, a first transistor which transmits a driving current to the light emitting diode, at least one switching transistor connected to the first transistor and including a first sub-transistor and a second sub-transistor connected to each other through a common node, and a back-gate terminal connected to a first power supply and the common node, and overlapping the second sub-transistor.

This application claims priority to Korean Patent Application No. 10-2022-0047578, filed on Apr. 18, 2022, and all the benefits accruing therefrom under 35 U.S.C. § 119, the content of which in its entirety is herein incorporated by reference.

### BACKGROUND

### 1. Field

Embodiments relate to a display device. More particularly, embodiments relate to a pixel circuit included in the display device.

### 2. Description of the Related Art

Research is continuing to minimize battery consumption of various electronic devices widely used in real life, such as smartphones, laptop computers, and tablet personal computers (PCs).

These electronic devices may include a display device. By minimizing power consumption of the display device, battery consumption of electronic devices may be minimized. For example, a low-frequency driving method for driving the display device at a relatively low frequency is proposed to reduce power consumption of the display device.

### SUMMARY

When a display device is driven by a low-frequency driving method to reduce power consumption, one frame period is increased such that the leakage current in the pixel may be increased, and the leakage current may cause a difference in luminance of the corresponding pixel between the two frames, resulting in a flicker phenomenon.

Embodiments provide a display device with improved low-frequency characteristics.

A display device according to an embodiment includes a light emitting diode, a first transistor which transmits a driving current to the light emitting diode, at least one switching transistor connected to the first transistor, where the at least one switching transistor includes a first sub-transistor and a second sub-transistor connected to each other through a common node, and a back-gate terminal connected to a first power supply and the common node, where the back-gate terminal overlaps the second sub-transistor.

In an embodiment, the display device may further include a first capacitor connected to the common node and the back-gate terminal and a second capacitor connected to the first power supply and the common node.

In an embodiment, the display device may further include a storage capacitor connected to the first power supply and the first transistor.

In an embodiment, the at least one switching transistor may further include a second transistor connected to a source terminal of the first transistor, a third transistor connected to a drain terminal of the first transistor and a fourth transistor connected to a gate terminal of the first transistor.

In an embodiment, the third transistor may be connected to the fourth transistor.

In an embodiment, the third transistor may be defined by the common node, the first sub-transistor, and the second sub-transistor, the first sub-transistor may be connected to the common node and the storage capacitor, and the second sub-transistor may overlap the back-gate terminal and may be connected to the common node and the first transistor.

In an embodiment, the fourth transistor may be defined by the common node, the first sub-transistor, and the second sub-transistor, the first sub-transistor may be connected to the common node and the storage capacitor, and the second sub-transistor may overlap the back-gate terminal and may be connected to the common node and an initialization voltage.

A display device according to an embodiment includes a substrate, a first transistor disposed on the substrate, a light emitting diode disposed on the first transistor, and connected to the first transistor, at least one switching transistor disposed on the substrate, where the at least one switching transistor includes an active layer including a first conductive area, a second conductive area, a first channel area, a second channel area, and a common conductive area, where the first conductive area and the second conductive area are spaced apart from each other, the first channel area and the second channel area are positioned between the first conductive area and the second conductive area, and the common conductive area positioned between the first channel area and the second channel area, and a lower pattern disposed under the active layer and overlapping the common conductive area and the second channel area.

In an embodiment, the lower pattern may be spaced apart from the first channel area in a plan view.

In an embodiment, the at least one switching transistor may include a first sub-transistor and a second sub-transistor which are connected to each other.

In an embodiment, the first sub-transistor may include the first channel area and a first gate electrode overlapping the first channel area.

In an embodiment, the second sub-transistor may include the second channel area and a second gate electrode overlapping the second channel area.

In an embodiment, the display device may further include an upper pattern disposed on the active layer, overlapping the common conductive area, and spaced apart from the first channel area and the second channel area in a plan view.

In an embodiment, the lower pattern may define a first capacitor with the common conductive area, and the upper pattern may define a second capacitor with the common conductive area.

In an embodiment, the display device may further include a power supply line disposed on the at least one switching transistor.

In an embodiment, the power supply line may be connected to the lower pattern and the upper pattern.

In an embodiment, the active layer may further include an active pattern extended from the first channel area and the second channel area, and the first transistor may include the active pattern and a first electrode disposed on the active pattern and overlapping the active pattern.

In an embodiment, the at least one switching transistor may include at least one selected from a second transistor, a third transistor, and a fourth transistor, and where the second transistor includes a second electrode spaced apart from the first electrode, the third transistor may be defined by a third electrode spaced apart from the first electrode and the second electrode, and the fourth transistor may be defined by a fourth electrode spaced apart from the first electrode, the second electrode, and the third electrode.

In an embodiment, the third transistor may be defined by the first channel area, the second channel area, and the common conductive area, and the first electrode may be connected to the first channel area.

In an embodiment, the fourth transistor may be defined by the first channel area, the second channel area, and the common conductive area, and the first electrode may be connected to the first channel area.

In a display device according to embodiments of the disclosure, the pixel included in the display device includes the first capacitor and the second capacitor between the first sub-transistor and the second sub-transistor, such that leakage current from flowing into the storage capacitor may be effectively prevented. In such embodiments, the pixel includes the back-gate terminal overlapping the second sub-transistor (i.e., the lower pattern overlapping the channel region included in the second sub-transistor), such that the leakage current may flow into a direction of the second sub-transistor, thereby the leakage current from flowing into the storage capacitor may be effectively prevented. Accordingly, by reducing the leakage current, the low-frequency characteristics of the display device may be improved.

### BRIEF DESCRIPTION OF THE DRAWINGS

FIG. 1 is a block diagram illustrating a display device according to an embodiment.

FIG. 2 is a circuit diagram illustrating an embodiment of a pixel included in the display device of FIG. 1.

FIG. 3 is a circuit diagram illustrating an alternative embodiment of a pixel included in the display device of FIG. 1.

FIG. 4 is a circuit diagram illustrating another alternative embodiment of a pixel included in the display device of FIG. 1.

FIG. 5 is a plan view illustrating a display device according to an embodiment.

FIGS. 6 to 8 are plan views showing an embodiment of a pixel included in the display device of FIG. 5.

FIG. 9 is an enlarged plan view of area A of FIG. 6.

FIG. 10 is a cross-sectional view taken along lines I-I′ and II-II′ of FIG. 9.

FIG. 11 is a plan view showing an alternative embodiment corresponding to FIG. 6.

FIG. 12 is an enlarged plan view of area B of FIG. 11.

FIG. 13 is a cross-sectional view taken along lines III-III′ and IV-IV′ of FIG. 12.

FIG. 14 is a plan view showing another alternative embodiment corresponding to FIG. 6.

FIG. 15 is an enlarged view of area C of FIG. 14.

FIG. 16 is an enlarged view of area D of FIG. 14.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings. The same reference numerals are used for the same components in the drawings, and any repetitive detailed descriptions of the same components will be omitted or simplified.

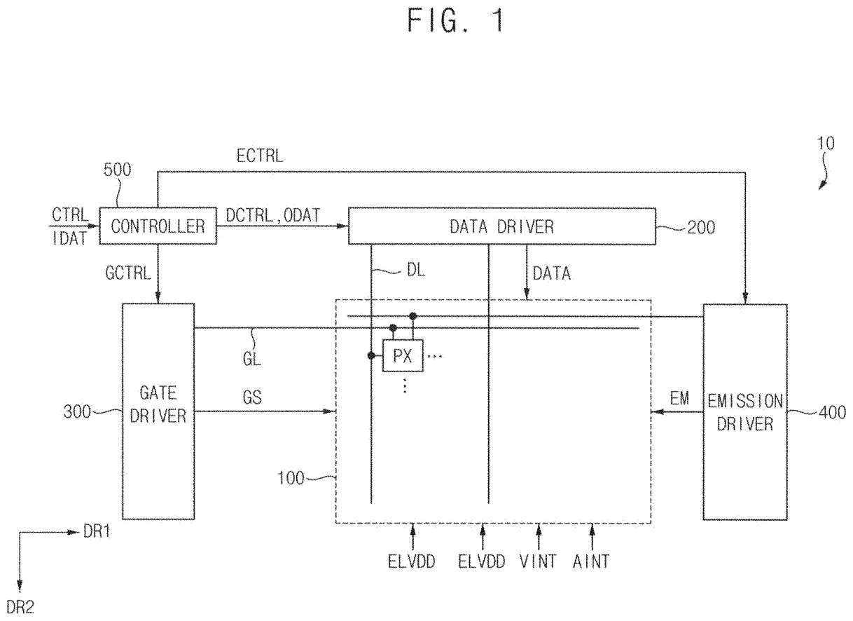

FIG. 1 is a block diagram illustrating a display device according to an embodiment.

Referring to FIG. 1, an embodiment of the display device 10 may include a pixel unit 100, a data driver 200, a gate driver 300, a emission driver 400, and a controller 500.

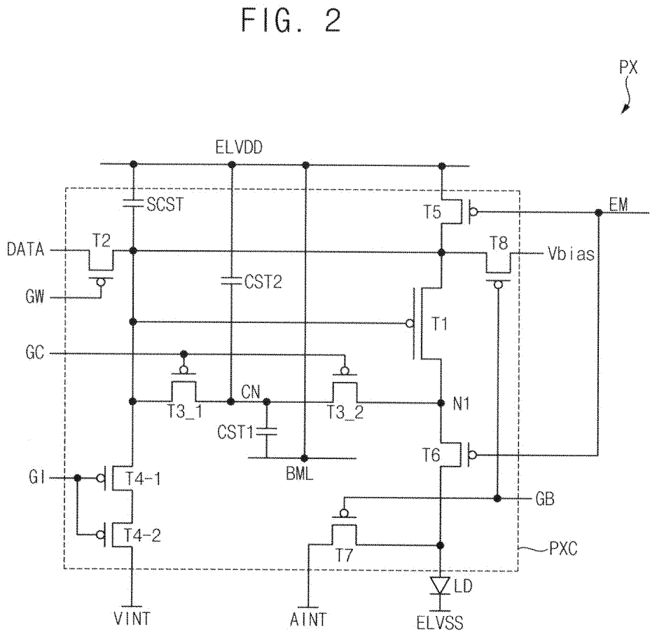

The pixel unit 100 may include a plurality of pixels PX. Each of the pixels PX may emit light having a preset color. In an embodiment, the pixel unit 100 may have an RGBG pixel structure, and each of the pixels PX may emit red, green, or blue light. Each of the pixels PX may include a pixel circuit (e.g., the pixel circuit PXC of FIG. 2) and a light emitting diode (e.g., the light emitting diode LD of FIG. 2). Each of the pixels PX may be driven through the pixel circuit.

In an embodiment, the data driver 200 may be implemented as one or more integrated circuits (ICs). In an embodiment, the data driver 200 may be mounted on the pixel unit 100 or integrated in a peripheral portion of the pixel unit 100.

The data driver 200 may generate a data voltage DATA based on an output image data ODAT and a data control signal DCTRL. In an embodiment, for example, the data driver 200 may generate the data voltage DATA corresponding to the output image data ODAT and output the data voltage DATA in response to the data control signal DCTRL. The data driver 200 may output the data voltage DATA through a data line DL. In an embodiment, for example, the data driver 200 may output the data voltage DATA to the pixels PX through the data line DL.

The output image data ODAT may be RGB data for an image displayed in the pixel unit 100, and the data control signal DCTRL may include an output data enable signal, a horizontal start signal, and a load signal.

The gate driver 300 may generate a gate signal GS based on a gate control signal GCTRL. The gate signal GS may be a clock signal. The gate signal GS may include a turn-on voltage which turns on the transistor and a turn-off voltage which turns off the transistor. The gate driver 300 may sequentially output the gate signal GS through the gate line GL. In an embodiment, for example, the gate driver 300 may output the gate signal GS to the pixels PX through the gate line GL. The gate control signal GCTRL may include a vertical start signal, a clock signal, and the like. In an embodiment, the gate driver 300 may be mounted on the pixel unit 100 or integrated in a peripheral portion of the pixel unit 100. In an embodiment, the gate driver 300 may be implemented as one or more ICs.

The emission driver 400 may generate an emission driving signal EM based on an emission control signal ECTRL. The emission driving signal EM may be a clock signal and may include the turn-on voltage and the turn-off voltage. The emission driver 400 may sequentially output the emission driving signal EM. The emission control signal ECTRL may include a vertical start signal, a clock signal, and the like. In an embodiment, the emission driver 400 may be mounted on the pixel unit 100 or integrated in a peripheral portion of the pixel unit 100. In an embodiment, the emission driver 400 may be implemented as one or more ICs.

The controller 500 (e.g., timing controller T-CON) may receive input image data IDAT and a control signal CTRL from an external host processor (e.g., GPU). In an embodiment, for example, the input image data IDAT may be RGB data including red image data, green image data, and blue image data. The controller 500 may generate the gate control signal GCTRL, the data control signal DCTRL, and the output image data ODAT based on the input image data IDAT and the control signal CTRL.

A first voltage ELVDD may be applied to the pixel unit 100. The first voltage ELVDD may be applied to the pixel unit 100 through a power line. A second voltage ELVSS (e.g., a low power voltage) may be applied to the pixel unit 100. The second voltage ELVSS may be applied to the pixel unit 100 through a common electrode. A transistor initialization voltage VINT and an anode initialization voltage AINT may be applied to the pixel unit 100.

FIG. 2 is a circuit diagram illustrating an embodiment of a pixel included in the display device of FIG. 1.

Referring to FIGS. 1 and 2, an embodiment of the pixel PX may be driven through the pixel circuit PXC. The pixel PX may include the pixel circuit PXC and the light emitting diode LD. The pixel circuit PXC may include a plurality of transistors and at least one capacitor.

In an embodiment, the pixel circuit PXC may include a driving transistor, at least one switching transistor, and a storage capacitor SCST. In an embodiment, for example, the pixel circuit PXC may include a first transistor T1 serving as the driving transistor, and at least one transistor connected to the first transistor T1 (e.g., a second transistor T2, a third transistor T3, and a fourth transistor T4), a storage capacitor SCST, a first capacitor CST1, and a second capacitor CST2.

In an embodiment, the pixel circuit PXC may further include at least one other switching transistor. In an embodiment, for example, the pixel circuit PXC may include a fifth transistor T5 and/or a sixth transistor T6 for controlling an emission period of the pixel PX, and one electrode of the light emitting diode LD. In an embodiment, a seventh transistor T7 for transmitting the transistor initialization voltage VINT and an eighth transistor T8 for transmitting a bias voltage Vbias may be selectively further included in the pixel circuit PXC.

The first transistor T1 may include a first gate terminal, a first source terminal, and a first drain terminal. The first source terminal of the first transistor T1 may receive the data voltage DATA. The first drain terminal of the first transistor T1 may be electrically connected to the light emitting diode LD through the sixth transistor T6. The first transistor T1 may generate a driving current. The first transistor T1 may transmit the driving current to the light emitting diode LD.

The second transistor T2 may receive a first gate signal GW through the gate line GL. In an embodiment, for example, the first gate signal GW may be referred to as a write gate signal GW. The second transistor T2 may receive the data voltage DATA through the data line DL. The second transistor T2 may be connected to the first source terminal of the first transistor T1. During a period in which the second transistor T2 is turned on, the data voltage DATA may be provided to the first transistor T1.

The second transistor T2 may be turned on or off in response to the first gate signal GW. In an embodiment, for example, where the second transistor T2 is a P-channel metal-oxide-semiconductor (PMOS) transistor, the second transistor T2 may be turned off when the first gate signal GW has a positive voltage level, and may be turned on when the first gate signal GW has a negative voltage level.

In an embodiment, the third transistor T3 may have a dual-gate structure. In an embodiment, for example, the third transistor T3 may include a common node CN, a first sub-transistor T3-1, and a second sub-transistor T3-2. The first sub-transistor T3-1 and the second sub-transistor T3-2 2 of the third transistor T3 may be connected to each other through the common node CN.

The first sub-transistor T3-1 2 of the third transistor T3 may be connected to the common node CN and the first storage capacitor SCST. The first sub-transistor T3-1 may be connected to the first gate terminal of the first transistor T1. The second sub-transistor T3-2 2 of the third transistor T3 may be connected to the common node CN and the first drain terminal of the first transistor T1.

The first sub-transistor T3-1 and the second sub-transistor T3-2 of the third transistor T3 may receive a second gate signal GC. In an embodiment, for example, the second gate signal GC may be referred to as a compensation control signal GC. In such an embodiment where the third transistor T3 has a dual-gate structure, reliability of the third transistor T3 may be improved.

The third transistor T3 may be turned on or off in response to the second gate signal GC. In an embodiment, for example, where the third transistor T3 is a PMOS transistor, the third transistor T3 may be turned off when the second gate signal GC has a positive voltage level, and may be turned on when the second gate signal GC has a negative voltage level. During a period in which the third transistor T3 is turned on in response to the second gate signal GC, the third transistor T3 may diode-connect the first transistor T1 or connect the first transistor T1 in a diode form. Accordingly, the third transistor T3 may compensate for a threshold voltage of the first transistor T1.

The fourth transistor T4 may have a dual-gate structure. The fourth transistor T4 may include a first sub-transistor T4-1 and a second sub-transistor T4-2. The first sub-transistor T4-1 and the second sub-transistor T4-2 of the fourth transistor T4 may be connected to each other.

The fourth transistor T4 may be connected to the third transistor T3 and the first gate terminal of the first transistor T1. The first sub-transistor T4-1 of the fourth transistor T4 may be connected to the storage capacitor SCST and the first sub-transistor T3-1 of the third transistor T3. The second sub-transistor T4-2 of the fourth transistor T4 may be connected to a transistor initialization voltage VINT.

The first sub-transistor T4-1 and the second sub-transistor T4-2 of the fourth transistor T4 may receive a third gate signal GI. In an embodiment, for example, the third gate signal GI may be referred to as an initialization gate signal GI. In such an embodiment where the fourth transistor T4 has a dual-gate structure, reliability of the fourth transistor T4 may be improved. The fourth transistor T4 may connect the first gate terminal of the first transistor T1 and the transistor initialization voltage VINT.

The fourth transistor T4 may be turned on or off in response to the third gate signal GI. In an embodiment, for example, where the fourth transistor T4 is a PMOS transistor, the fourth transistor T4 is turned off when the third gate signal GI has a positive voltage level, and may be turned on when the third gate signal GI has a negative voltage level.

During a period in which the fourth transistor T4 is turned on in response to the third gate signal GI, the first gate terminal of the first transistor T1 may be electrically connected to the transistor initialization voltage VINT. Accordingly, the fourth transistor T4 may transmit the transistor initialization voltage VINT to the first gate terminal of the first transistor T1 in response to the third gate signal GI.

The fifth transistor T5 may receive the emission driving signal EM. The fifth transistor T5 may receive the first voltage ELVDD. The fifth transistor T5 may be connected to the first source terminal of the first transistor T1. When the fifth transistor T5 is turned on in response to the light emission driving signal EM, the fifth transistor T5 may provide the first voltage ELVDD to the first transistor T1.

The sixth transistor T6 may receive the emission driving signal EM. The sixth transistor T6 may be connected to the first drain terminal of the first transistor T1. The sixth transistor T6 may be connected to the light emitting diode LD. When the sixth transistor T6 is turned on in response to the emission driving signal EM, the sixth transistor T6 may provide the driving current to the light emitting diode LD. In an embodiment, for example, each of the fifth transistor T5 and the sixth transistor T6 may be referred to as an emission control transistor.

The seventh transistor T7 may receive a fourth gate signal GB. In an embodiment, for example, the fourth gate signal GB may be referred to as a bypass gate signal GB. The seventh transistor T7 may be connected to the light emitting diode LD. The seventh transistor T7 may receive a anode initialization voltage AINT. When the seventh transistor T7 is turned on in response to the fourth gate signal GB, the seventh transistor T7 may provide the anode initialization voltage AINT to the light emitting diode LD. Accordingly, the seventh transistor T7 may initialize the light emitting diode LD by the anode initialization voltage AINT. In an embodiment, for example, the seventh transistor T7 may be referred to as an anode initialization transistor.

The eighth transistor T8 may receive the fourth gate signal GB. The eighth transistor T8 may receive a bias voltage Vbias. When the eighth transistor T8 is turned on in response to the fourth gate signal GB, the eighth transistor T8 may provide the bias voltage Vbias to the first transistor T1.

The storage capacitor SCST may include a first terminal and a second terminal. The first terminal of the storage capacitor SCST may be connected to the first transistor T1, and the second terminal of the storage capacitor SCST may receive the first voltage ELVDD (e.g., a high power supply voltage). The storage capacitor SCST may maintain the voltage level of the first gate terminal of the first transistor T1 during an inactivation period of the first gate signal GW.

The light emitting diode LD may include the first terminal (e.g., an anode terminal) and a second terminal (e.g., a cathode terminal). The first terminal of the light emitting diode LD may be connected to the sixth transistor T6 to receive the driving current, and the second terminal may receive the second voltage ELVSS. The light emitting diode LD may generate light having a luminance corresponding to the driving current.

The pixel circuit PXC may further include a back-gate terminal BML. The back-gate terminal BML may be connected to the first voltage ELVDD and the common node CN. Accordingly, the back-gate terminal BML may receive the first voltage ELVDD.

The back-gate terminal BML may overlap the second sub-transistor T3-2 of the third transistor T3. Accordingly, the back-gate terminal BML may serve as a back-gate terminal of the second sub transistor T3-2 of the third transistor T3.

The first capacitor CST1 may include a first terminal and a second terminal. The first terminal of the first capacitor CST1 may be connected to the common node CN, and the second terminal of the first capacitor CST1 may be connected to the back-gate terminal BML. The back-gate terminal BML may provide the first voltage ELVDD to the second terminal of the first capacitor CST1.

The second capacitor CST2 may include a first terminal and a second terminal. The first terminal of the second capacitor CST2 may be connected to the first voltage ELVDD, and the second terminal of the second capacitor CST2 may be connected to the common node CN.

In an embodiment, as described above, the pixel PX includes the first capacitor CST1 and the second capacitor CST2 connected to the common node CN, such that a voltage applied to the common node CN may be maintained relatively constant. In such an embodiment, the pixel PX includes the back-gate terminal BML overlapping the second sub transistor T3-2 of the third transistor T3, such that a leakage current may flow more into a direction of the second sub-transistor T3-2 than a direction of the first sub transistor T3-1. In such an embodiment, a constant voltage may be applied to the storage capacitor SCST. Accordingly, by reducing the leakage current, low-frequency characteristics of the display device 10 may be improved.

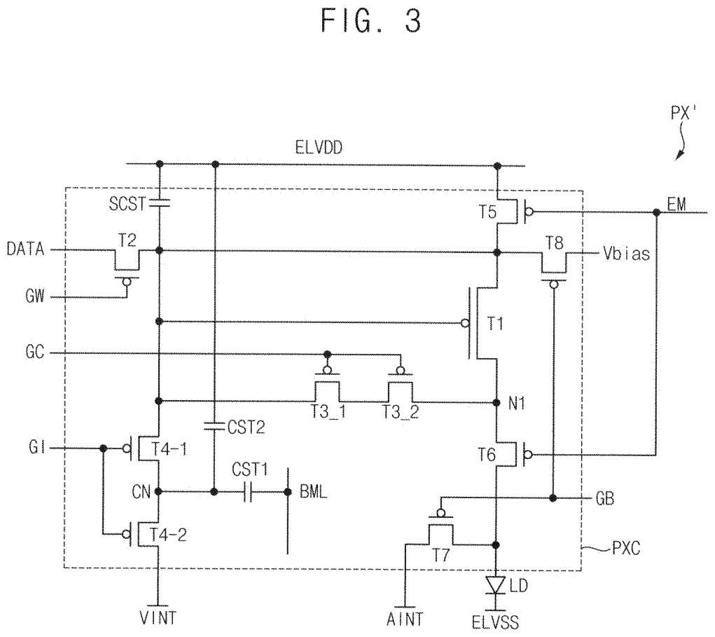

FIG. 3 is a circuit diagram illustrating an alternative embodiment of a pixel included in the display device of FIG. 1.

In describing a pixel PX′ of FIG. 3, any repetitive detailed description of the same or like elements as those of the pixel PX described above with reference to FIG. 2 may be omitted or simplified.

Referring to FIGS. 1 and 3, the third transistor T3 may have a dual-gate structure. In an embodiment, for example, the third transistor T3 may include a first sub-transistor T3-1 and a second sub-transistor T3-2. The first sub-transistor T3-1 and the second sub-transistor T3-2 of the third transistor T3 may be connected to each other.

The first sub-transistor T3-1 of the third transistor T3 may be connected to the first storage capacitor SCST and the first gate terminal of the first transistor T1. The second sub-transistor T3-2 of the third transistor T3 may be connected to the first drain terminal of the first transistor T1.

The first sub-transistor T3-1 and the second sub-transistor T3-2 of the third transistor T3 may receive a second gate signal GC.

In an embodiment, the fourth transistor T4 may have a dual-gate structure. In an embodiment, for example, the fourth transistor T4 may include a common node CN, a first sub-transistor T4-1, and a second sub-transistor T4-2. The first sub-transistor T4-1 and the second sub-transistor T4-2 of the fourth transistor T4 may be connected to each other through the common node CN.

The fourth transistor T4 may be connected to the third transistor T3 and the first gate terminal of the first transistor T1. The first sub-transistor T4-1 of the fourth transistor T4 may be connected to the common node CN, the storage capacitor SCST, and the first sub-transistor T3-1 of the third transistor T3. The second sub-transistor T4-2 of the fourth transistor T4 may be connected to the common node CN and the transistor initialization voltage VINT.

The first sub-transistor T4-1 and the second sub-transistor T4-2 of the fourth transistor T4 may receive a third gate signal GI. The fourth transistor T4 may connect the first gate terminal of the first transistor T1 and the transistor initialization voltage VINT.

The storage capacitor SCST may include a first terminal and a second terminal. The first terminal of the storage capacitor SCST may be connected to the first transistor T1, and the second terminal of the storage capacitor SCST may receive the first voltage ELVDD. The storage capacitor SCST may maintain the voltage level of the first gate terminal of the first transistor T1 during the inactivation period of the first gate signal GW.

The pixel circuit PXC may further include a back-gate terminal BML. The back-gate terminal BML may be connected to the first voltage ELVDD and the common node CN. The back-gate terminal BML may overlap the second sub-transistor T4-2 of the fourth transistor T4. Accordingly, the back-gate terminal BML may serve as a back-gate terminal of the second sub transistor T4-2 of the fourth transistor T4.

The first capacitor CST1 may include a first terminal and a second terminal. The first terminal of the first capacitor CST1 may be connected to the common node CN, and the second terminal of the first capacitor CST1 may be connected to the back-gate terminal BML.

The second capacitor CST2 may include a first terminal and a second terminal. The first terminal of the second capacitor CST2 may be connected to the first voltage ELVDD, and the second terminal of the second capacitor CST2 may be connected to the common node CN.

In an embodiment, as described above, the pixel PX′ includes the first capacitor CST1 and the second capacitor CST2 connected to the common node CN, such that the voltage applied to the common node CN may be maintained relatively constant. In such an embodiment, the pixel PX′ includes the back-gate terminal BML overlapping the second sub-transistor T4-2 of the fourth transistor T4, such that a leakage current may flow more in a direction of the second sub-transistor T4-2 than a direction of the first sub-transistor T4-1. In such an embodiment, a constant voltage may be applied to the storage capacitor SCST. Accordingly, by reducing the leakage current, the low-frequency characteristics of the display device 10 may be improved.

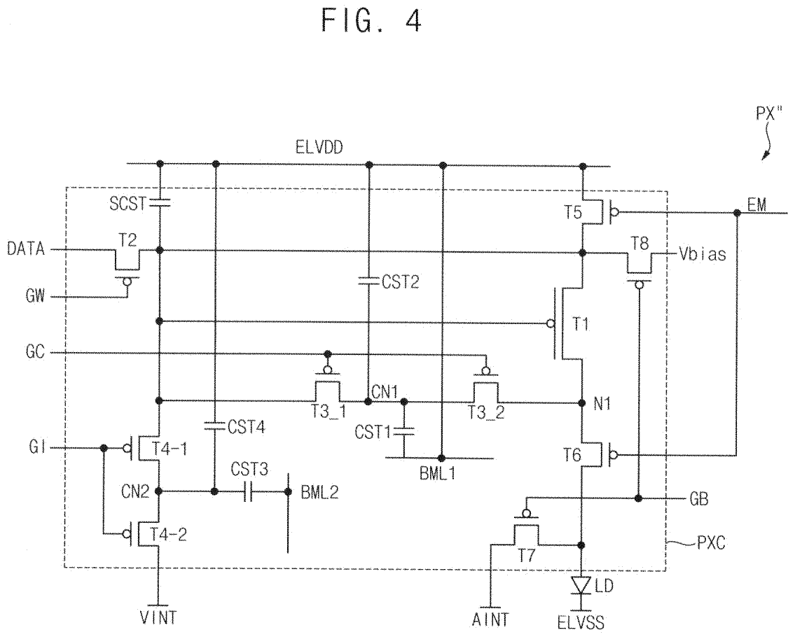

FIG. 4 is a circuit diagram illustrating another alternative embodiment of a pixel included in the display device of FIG. 1.

Hereinafter, any repetitive detailed description of the same or like elements of the pixel PX″ of FIG. 4 as those of the pixel PX or PX′ described above with reference to FIGS. 2 and 3 may be omitted or simplified.

Referring to FIGS. 1 and 4, in an embodiment, the third transistor T3 may have a dual-gate structure. In an embodiment, for example, the third transistor T3 may include a first common node CN1, a first sub transistor T3-1, and a second sub transistor T3-2. The first sub-transistor T3-1 and the second sub-transistor T3-2 of the third transistor T3 may be connected to each other through the first common node CN1.

The first sub-transistor T3-1 of the third transistor T3 may be connected to the first common node CN1 and the first storage capacitor SCST. The first sub-transistor T3-1 of the third transistor T3 may be connected to the first gate terminal of the first transistor T1. The second sub-transistor T3-2 may be connected to the first common node CN1 and the first drain terminal of the first transistor T1.

The first sub-transistor T3-1 and the second sub-transistor T3-2 of the third transistor T3 may receive the second gate signal GC.

In an embodiment, the fourth transistor T4 may have a dual-gate structure. In an embodiment, for example, the fourth transistor T4 may include a second common node CN2, a first sub-transistor T4-1, and a second sub-transistor T4-2. The first sub-transistor T4-1 and the second sub-transistor T4-2 of the fourth transistor T4 may be connected to each other through the second common node CN2.

The fourth transistor T4 may be connected to the third transistor T3 and the first gate terminal of the first transistor T1. The first sub-transistor T4-1 of the fourth transistor T4 may be connected to the second common node CN2, the storage capacitor SCST, and the first sub-transistor T3-1 of the third transistor T3. The second sub-transistor T4-2 of the fourth transistor T4 may be connected to the second common node CN2 and the transistor initialization voltage VINT.

The first sub-transistor T4-1 and the second sub-transistor T4-2 of the fourth transistor T4 may receive the third gate signal GI.

The storage capacitor SCST may include a first terminal and a second terminal. The first terminal of the storage capacitor SCST may be connected to the first transistor T1, and the second terminal of the storage capacitor SCST may receive the first voltage ELVDD.

The pixel circuit PXC may further include a first back-gate terminal BML1 and a second back-gate terminal BML2. The first back-gate terminal BML1 may be connected to the first voltage ELVDD and the first common node CN1. The first back-gate terminal BML1 may overlap the second sub transistor T3-2 of the third transistor T3. Accordingly, the first back-gate terminal BML1 may serve as a back-gate terminal of the second sub transistor T3-2 of the third transistor T3.

The second back-gate terminal BML2 may be connected to the first voltage ELVDD and the second common node CN2. The second back-gate terminal BML2 may overlap the second sub transistor T4-2 of the fourth transistor T4. Accordingly, the second back-gate terminal BML2 may serve as a back-gate terminal of the second sub transistor T4-2 of the fourth transistor T4.

The first capacitor CST1 may include a first terminal and a second terminal. The first terminal of the first capacitor CST1 may be connected to the first common node CN1, and the second terminal of the first capacitor CST1 may be connected to the first back-gate terminal BML1.

The second capacitor CST2 may include a first terminal and a second terminal. The first terminal of the second capacitor CST2 may be connected to the first voltage ELVDD, and the second terminal of the second capacitor CST2 may be connected to the first common node CN1.

The third capacitor CST3 may include a first terminal and a second terminal. The first terminal of the third capacitor CST3 may be connected to the second common node CN2, and the second terminal of the third capacitor CST3 may be connected to the second back-gate terminal BML2.

The fourth capacitor CST4 may include a first terminal and a second terminal. The first terminal of the fourth capacitor CST4 may be connected to the first voltage ELVDD, and the second terminal of the fourth capacitor CST4 may be connected to the second common node CN2.

In an embodiment, as described above, the pixel PX″ includes the first capacitor CST1 and the second capacitor CST2 connected to the first common node CN1, and the third capacitor CST3 and the fourth capacitor CST4 connected to the second common node CN2, such that a voltage applied to each of the first common node CN1 and the second common node CN2 may be maintained relatively constant. In such an embodiment, the pixel PX″ includes the first back-gate terminal BML1 overlapping the second sub-transistor T3-2 of the third transistor T3 and the second back-gate terminal BML2 overlapping the second sub-transistor T4-2 of the fourth transistor T4, such that a leakage current may flow more into a direction of the second sub-transistor T3-2, T4-2 than a direction of the first sub transistor T3-1, T4-1. In such an embodiment, a constant voltage may be applied to the storage capacitor SCST. Accordingly, by reducing the leakage current, the low-frequency characteristics of the display device 10 may be improved.

It would be understood that the connection structure of the pixel circuit PXC and the light emitting diode LD illustrated in FIGS. 2 to 4 are merely examples and may be variously changed or modified.

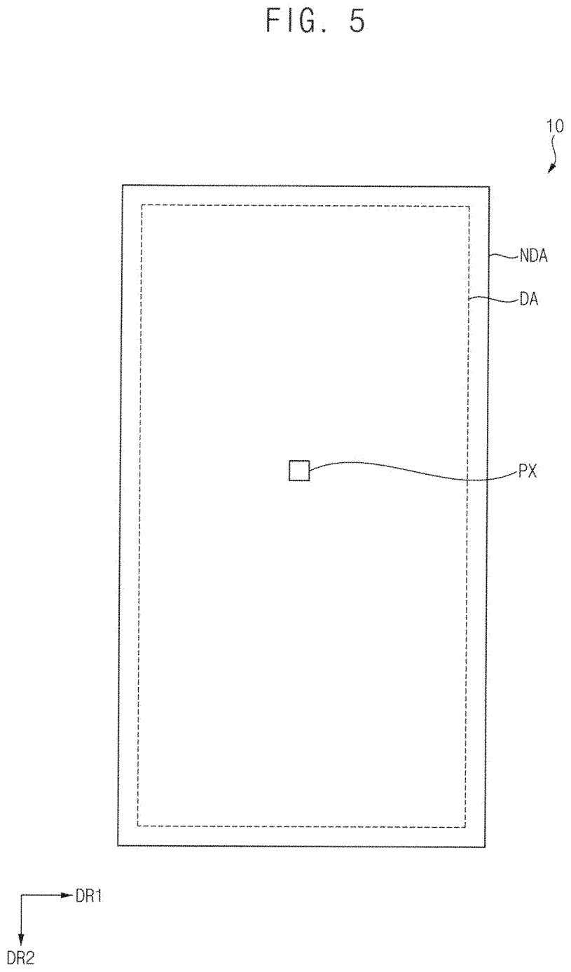

FIG. 5 is a plan view illustrating a display device according to an embodiment.

Referring to FIG. 5, an embodiment of the display device 10 may include a display area DA and a non-display area NDA. The display area DA may display an image or define a screen. A plurality of pixels PX that emit light and wirings which transmit a driving signal to the pixels PX may be disposed in the display area DA. In an embodiment, for example, the wirings include a gate line (e.g., the gate line GL of FIG. 1) and a data line (e.g., the data line DL of FIG. 1). The gate lines may transmit a gate signal, and the data lines may transmit a data signal.

The non-display area NDA may be an area which does not display a screen. Wirings for driving and drivers may be disposed in the non-display area NDA. In an embodiment, for example, a gate driver, a emission driver, a pad, and a driving chip may be disposed in the non-display area NDA. In an embodiment, the non-display area NDA may be adjacent to the display area DA and surround four sides of the display area DA. However, embodiments according to the disclosure are not limited thereto, and alternatively, the non-display area NDA may surround three or less sides of the display area DA.

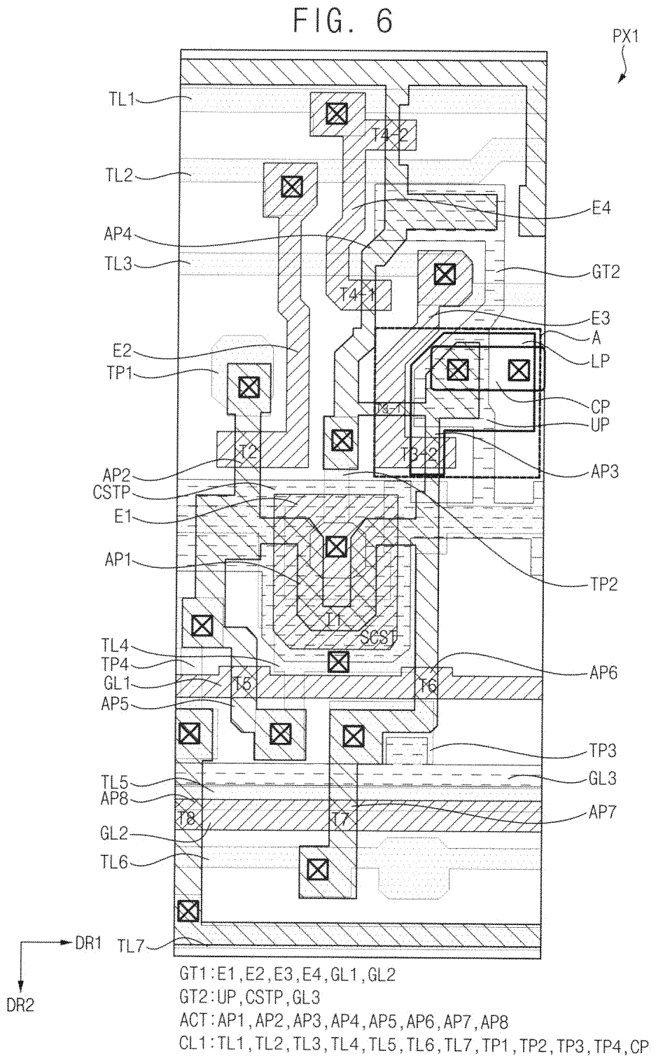

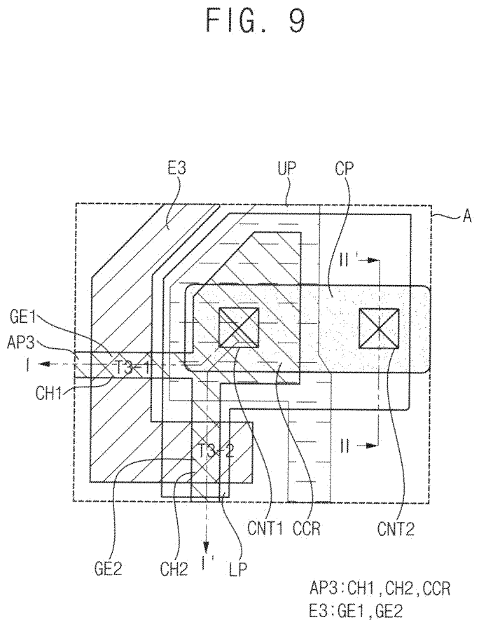

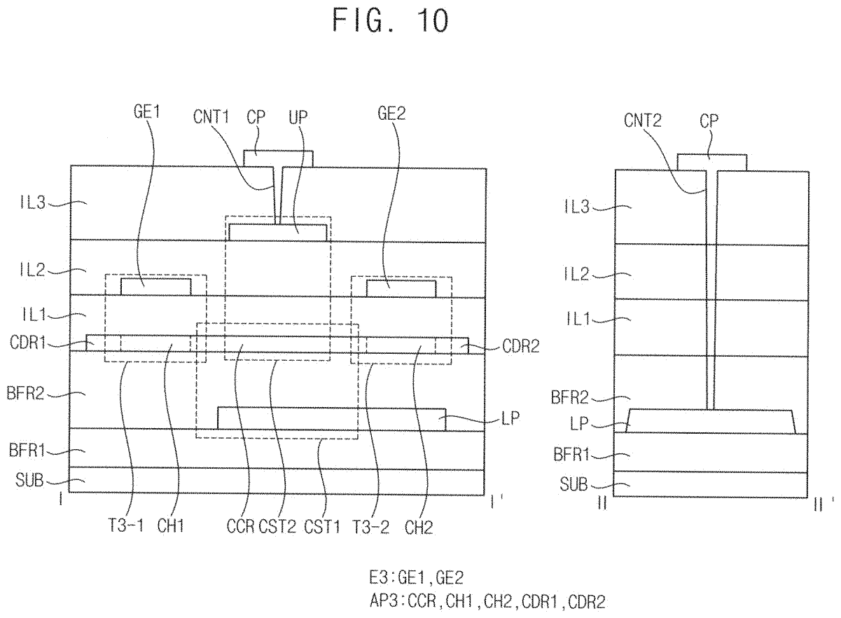

FIGS. 6 to 8 are plan views illustrating an embodiment of a pixel included in the display device of FIG. 5. FIG. 9 is an enlarged plan view of area A of FIG. 6. FIG. 10 is a cross-sectional view taken along lines I-I′ and II-II′ of FIG. 9.

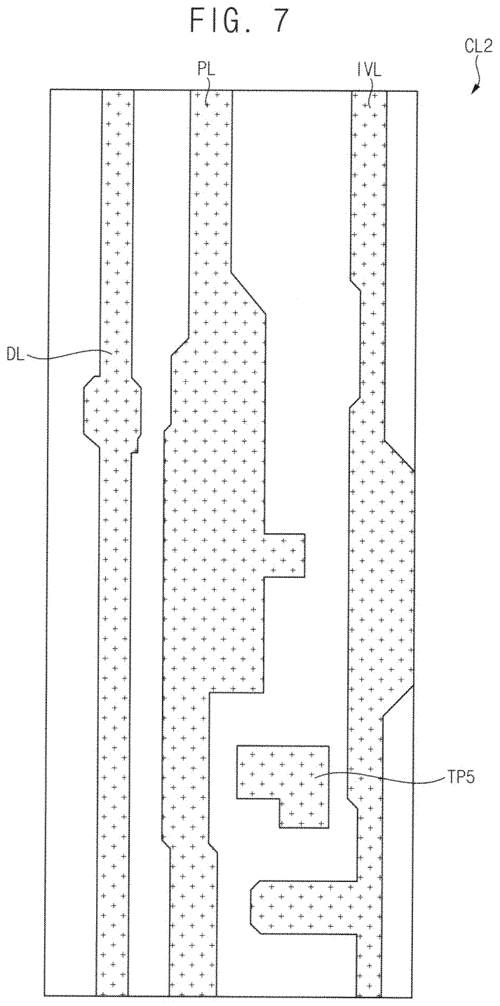

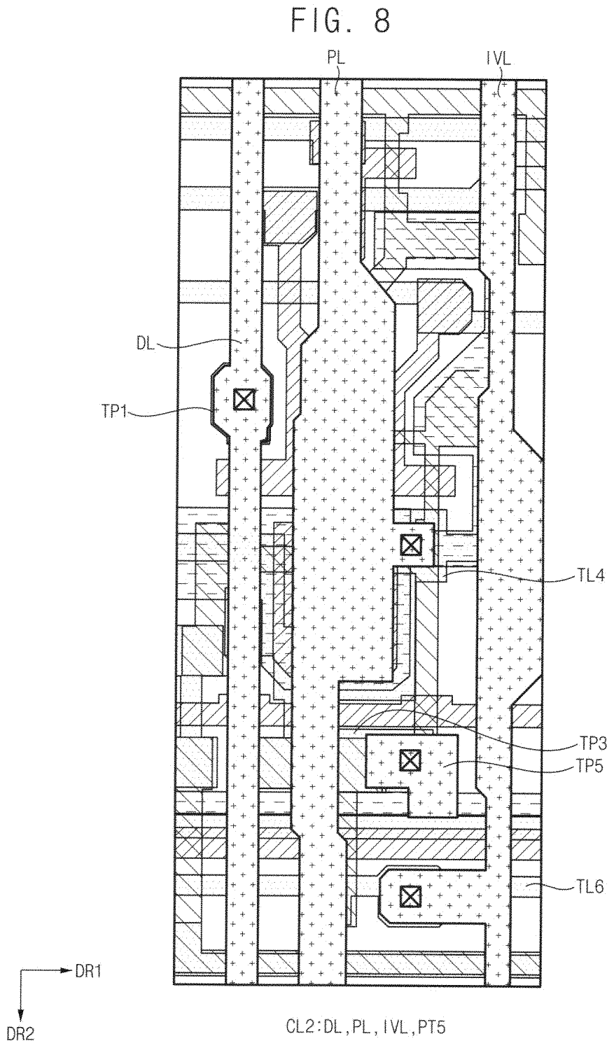

Particularly, FIG. 7 is a view illustrating a second conductive layer CL2 included in the pixel PX1, and FIG. 8 is a view in which the second conductive layer CL2 is disposed on the pixel PX1 of FIG. 6.

FIGS. 6 to 10 may be plan views of the pixel PX described above with reference to FIG. 2. Therefore, any repetitive detailed description of the same or like elements as those described above may be omitted or simplified.

Referring to FIGS. 5 to 10, the display device 10 may include a pixel PX1.

In an embodiment, the pixel PX1 may include a driving transistor, at least one switching transistor, a storage capacitor SCST, and a light emitting diode (e.g., the light emitting diode LD of FIG. 2). In an embodiment, for example, the pixel PX may include a first transistor T1 serving as the driving transistor, at least one switching transistor connected to the first transistor T1, a storage capacitor SCST, a first capacitor CST1, and a second capacitor CST2. The at least one switching transistor may include at least one selected from a second transistor T2, a third transistor T3, and a fourth transistor T4.

In an embodiment, the pixel circuit PXC may further include at least one other switching transistor. In an embodiment, for example, the pixel circuit PXC may be selectively further include a fifth transistor T5 and/or a sixth transistor T6 for controlling the emission period of the pixel PX, a seventh transistor T7 for transmitting the transistor initialization voltage VINT to one electrode of the light emitting diode LD and an eighth transistor T8 for transmitting the bias voltage Vbias.

The pixel PX1 may include a substrate SUB, a first buffer layer BFR1, a second buffer layer BFR2, first to fourth insulation layers, a lower pattern LP, an active layer ACT, a first gate layer GT1, a second gate layer GT2, a first conductive layer CL1, a second conductive layer CL2, and the light emitting diode.

The substrate SUB may have a structure in which at least one polymer film and at least one barrier layer are alternately stacked. In an embodiment, for example, the polymer film may include or be formed using an organic material such as polyimide, and the barrier layer may include or be formed using an inorganic material.

The first buffer layer BFR1 may be disposed on the substrate SUB, and the second buffer layer BFR2 may be disposed on the first buffer layer BFR1. The first buffer layer BFR1 and the second buffer layer BFR2 may prevent diffusion of metal atoms or impurities from the substrate SUB to the active layer ACT.

The lower pattern LP may be disposed between the first buffer layer BFR1 and the second buffer layer BFR2. The lower pattern LP may be disposed under the active layer ACT to overlap a portion of the active layer ACT. The lower pattern LP may include a conductive material.

The active layer ACT may be disposed on the second buffer layer BFR2. The active layer ACT may include a conductive material. The active layer ACT may include a plurality of active patterns AP1, AP2, AP3, AP4, AP5, AP6, AP7, and AP8. In an embodiment, for example, the active layer ACT may include a first active pattern AP1, a second active pattern AP2, a third active pattern AP3, a fourth active pattern AP4, and a fifth active pattern AP5, a sixth active pattern AP6, a seventh active pattern AP7, and an eighth active pattern AP8. In an embodiment, the first to seventh active patterns AP1, AP2, AP3, AP4, AP5, AP6, and AP7 may be connected to each other. In such an embodiment, the eighth active pattern AP8 may be spaced apart from the first to seventh active patterns AP1, AP2, AP3, AP4, AP5, AP6, and AP7.

The first insulation layer IL1 may cover the active layer ACT and may be disposed on the second buffer layer BFR2. The first insulation layer IL1 may include an insulating material.

The first gate layer GT1 may be disposed on the first insulation layer IL1. The first gate layer GT1 may include a conductive material. The first gate layer GT1 may include a first electrode E1, a second electrode E2, a third electrode E3, a fourth electrode E4, a first gate line GL1, and a second gate line GL2.

The first electrode E1 may be disposed on the first active pattern AP1 and overlap the first active pattern AP1. The first electrode E1 and the first active pattern AP1 may constitute a first transistor T1.

The second electrode E2 may be spaced apart from the first electrode E1, may be disposed on the second active pattern AP2, and may overlap the second active pattern AP2. The second electrode E2 and the second active pattern AP2 may constitute a second transistor T2.

The third electrode E3 may be spaced apart from the first electrode E1 and the second electrode E2, be disposed on the third active pattern AP3, and overlap the third active pattern AP3. The third electrode E3 and the third active pattern AP3 may constitute a third transistor T3.

The fourth electrode E4 may be spaced apart from the first to third electrodes E1, E2, and E3, be disposed on the fourth active pattern AP4, and overlap the fourth active pattern AP4. The fourth electrode E4 and the fourth active pattern AP4 may constitute a fourth transistor T4.

The first gate line GL1 may be spaced apart from the first to fourth electrodes E1, E2, E3, and E4, be disposed on the fifth active pattern AP5 and the sixth active pattern AP6 and overlap the fifth active pattern AP5 and the sixth active pattern AP6. The first gate line GL1 and the fifth active pattern AP5 may constitute a fifth transistor T5, and the first gate line GL1 and the sixth active pattern AP6 may constitute a sixth transistor T6.

The second gate line GL2 may be spaced apart from the first to fourth electrodes E1, E2, E3 and E4 and the first gate line GL1, be disposed on the seventh active pattern AP7 and the eighth active pattern AP8, and overlap the seventh active pattern AP7 and the eighth active pattern AP8. The second gate line GL2 and the seventh active pattern AP7 may constitute a seventh transistor T7, and the second gate line GL2 and the eighth active pattern AP8 may constitute an eighth transistor T8.

The second insulation layer IL2 may cover the first gate layer GT1 and may be disposed on the first insulation layer IL1. The second insulation layer IL2 may include an insulating material.

The second gate layer GT2 may be disposed on the second insulation layer IL2. The second gate layer GT2 may include a conductive material. The second gate layer GT2 may include a capacitor pattern CSTP, an upper pattern UP, and a third gate line GL3.

The capacitor pattern CSTP and the upper pattern UP may be connected to each other. The capacitor pattern CSTP may overlap the first electrode E1. The capacitor pattern CSTP may constitute the first electrode E1 and the storage capacitor SCST. The third gate line GL3 may be spaced apart from the capacitor pattern CSTP and the upper pattern UP, and extend in a first direction DR1.

In an embodiment, the upper pattern UP may be disposed on the third active pattern AP3 and partially overlap the third active pattern AP3.

The third insulation layer IL3 may cover the second gate layer GT2 and be disposed on the second insulation layer IL2. The third insulation layer IL3 may include an insulating material.

The first conductive layer CL1 may be disposed on the third insulation layer IL3. The first conductive layer CL1 may include a conductive material. The first conductive layer CL1 may include a first transmission line TL1, a second transmission line TL2, a third transmission line TL3, a fourth transmission line TL4, a fifth transmission line TL5, and a sixth transmission line TL6, a seventh transmission line TL7, a first transmission pattern TP1, a second transmission pattern TP2, a third transmission pattern TP3, a fourth transmission pattern TP4, and a connection pattern CP.

The first transmission line TL1, the second transmission line TL2, the third transmission line TL3, the fourth transmission line TL4, the fifth transmission line TL5, and the sixth transmission line TL6 may extend in the first direction DR1. The first transmission line TL1 may be connected to the fourth electrode E4, and the second transmission line TL2 may be connected to the second electrode E2. The third transmission line TL3 may be connected to the third electrode E3, and the fourth transmission line TL4 may be connected to the first electrode E1. The fifth transmission line TL5 may be a repair line, and the sixth transmission line TL6 may be connected to the seventh active pattern AP7. The seventh transmission line TL7 may be connected to the eighth active pattern AP8.

The first transmission pattern TP1 may be connected to the second active pattern AP2. The second transmission pattern TP2 may be connected to the first transistor T1 and the active layer ACT. The third transmission pattern TP3 may be connected to the light emitting diode, the sixth active pattern AP6, and the seventh active pattern AP7. The fourth transmission pattern TP4 may connect the first to seventh active patterns AP1, AP2, AP3, AP4, AP5, AP6, and AP7 with the eighth active pattern AP8.

The connection pattern CP may be connected to the upper pattern UP and the lower pattern LP.

The fourth insulation layer (not shown) may cover the connection pattern CP and be disposed on the third insulation layer IL3. The fourth insulation layer may include an insulating material.

The second conductive layer CL2 may be disposed on the fourth insulation layer. The second conductive layer CL2 may include a data line DL, a power line PL, an initialization voltage line IVL, and a fifth transmission pattern TP5.

The data line DL, the power line PL, the initialization voltage line IVL, and the fifth transmission pattern TP5 may be spaced apart from each other and extend in a second direction DR2 orthogonal to the first direction DR1.

The data line DL may be connected to the first transmission pattern TP1. The power line PL may be connected to the fourth transmission line TL4 and the connection pattern CP. The initialization voltage line IVL may be connected to the active layer ACT. The fifth transmission pattern TP5 may be connected to the third transmission pattern TP3.

The light emitting diode may be disposed on the second conductive layer CL2 and be electrically connected to the first to eighth transistors T1, T2, T3, T4, T5, T6, T7, and T8. The light emitting diode may receive a driving current from the first transistor T1.

A first gate signal (e.g., the first gate signal GW of FIG. 2) may be transmitted to the second transistor T2 through the second transmission line TL2 and the second electrode E2. A second gate signal (e.g., the second gate signal GC of FIG. 2) may be transmitted to the third transistor T3 through the third transmission line TL3 and the third electrode E3. A third gate signal (e.g., the third gate signal GI of FIG. 2) may be transmitted to the first transmission line TL1 and the fourth electrode E4 through the fourth transistor T4.

The emission driving signal (e.g., the emission driving signal EM of FIG. 2) may be transmitted to the fifth transistor T5 and the sixth transistor T6 through the first gate line GL1. A fourth gate signal (e.g., the fourth gate signal GB of FIG. 2) may be transmitted to the seventh transistor T7 and the eighth transistor T8 through the second gate line GL2.

A data voltage (e.g., the data voltage DATA of FIG. 2) may be transmitted to the second transistor T2 through the data line DL and the first transmission pattern TP1. A bias voltage (e.g., the bias voltage Vbias of FIG. 2) may be transmitted to the eighth transistor T8 through the seventh transmission line TL7.

A transistor initialization voltage (e.g., the transistor initialization voltage VINT of FIG. 2) may be transmitted to the fourth transistor T4 through the initialization voltage line IVL and the active layer ACT. The anode initialization voltage (e.g., the anode initialization voltage AINT of FIG. 2) may be transmitted to the seventh transistor T7 through the initialization voltage line IVL and the sixth transmission line TL6.

A first voltage (e.g., the first voltage ELVDD of FIG. 2) may be transmitted to the fifth transistor T5 and the storage capacitor SCST through the power line PL.

In an embodiment, as shown in FIG. 10, the third transistor T3 may have a dual-gate structure. Accordingly, the third active pattern AP3 may include a first conductive region CDR1, a second conductive region CDR2, a first channel region CH1, a second channel region CH2, and a common conductive region CCR. The first conductive region CDR1 and the second conductive region CDR2 may be spaced apart from each other. The first channel region CH1 and the second channel region CH2 may be positioned between the first conductive region CDR1 and the second conductive region CDR2. The common conductive region CCR may be positioned between the first channel region CH1 and the second channel region CH2.

The third transistor T3 may include a first sub-transistor T3-1 and a second sub-transistor T3-2. The first sub-transistor T3-1 of the third transistor T3 may include the first channel region CH1 and a first gate electrode GE1. The first gate electrode GE1 may be defined by a portion of the third electrode E3 and may overlap the first channel region CH1.

The second sub-transistor T3-2 of the third transistor T3 may include the second channel region CH2 and a second gate electrode GE2. The second gate electrode GE2 may be defined by another portion of the third electrode E3 and may overlap the second channel region CH2. The first gate electrode GE1 and the second gate electrode GE2 may constitute the third electrode E3, that is, the first gate electrode GE1 and the second gate electrode GE2 may be defined by portions of the third electrode E3, and thus the first sub-transistor T3-1 and the second sub-transistor T3-2 of the third transistor T3 may be connected to each other.

The lower pattern LP may overlap the common conductive region CCR and the second channel region CH2 of the third active pattern AP3. The lower pattern LP may be spaced apart from the first channel region CH1 of the third active pattern AP3 in a plan view or when viewed in a thickness direction of the substrate SUB or the display device 10. The upper pattern UP may overlap the common conductive region CCR. The upper pattern UP may be spaced apart from the first channel region CH1 and the second channel region CH2 in the plan view.

The lower pattern LP may constitute the common conductive region CCR of the third active pattern AP3 and the first capacitor CST1. The upper pattern UP may constitute the common conductive region CCR and the second capacitor CST2 of the third active pattern AP3.

The lower pattern LP and the upper pattern UP may be connected to the power line PL through the connection pattern CP. Accordingly, the first capacitor CST1 and the second capacitor CST2 may receive the first voltage ELVDD through the connection pattern CP.

The first active pattern AP1 may be connected to the third active pattern AP3 and extend from the first channel region CH1 and the second channel region CH2 of the third active pattern AP3. The first active pattern AP1 may be adjacent to the second channel region CH2 and be spaced apart from the first channel region CH1. The first transistor T1 may be disposed relatively adjacent to the second sub-transistor T3-2 of the third transistor T3 than the first sub-transistor T3-1 of the third transistor T3.

In an embodiment, the first channel region CH1 of the third active pattern AP3 may be connected to the first electrode E1. In an embodiment, the active layer ACT between the first channel region CH1 of the third active pattern AP3 and the fourth active pattern AP4 may be connected to the first electrode E1 through the second transmission pattern TP2. Accordingly, the first sub-transistor T3-1 of the third transistor T3 may be disposed relatively adjacent to the storage capacitor SCST.

In an embodiment, the pixel PX1 includes the first capacitor CST1 and the second capacitor CST2, such that a leakage current may be effectively prevented from flowing into the storage capacitor SCST. In such an embodiment, the pixel PX1 includes the lower pattern LP overlapping the second channel region CH2 included in the second sub transistor T3-2, such that the leakage current may flow into a direction of the second sub-transistor T3-2, thereby the leakage current may be effectively prevented from flowing into the storage capacitor SCST. Accordingly, by reducing the leakage current, the low-frequency characteristic of the display device 10 may be improved.

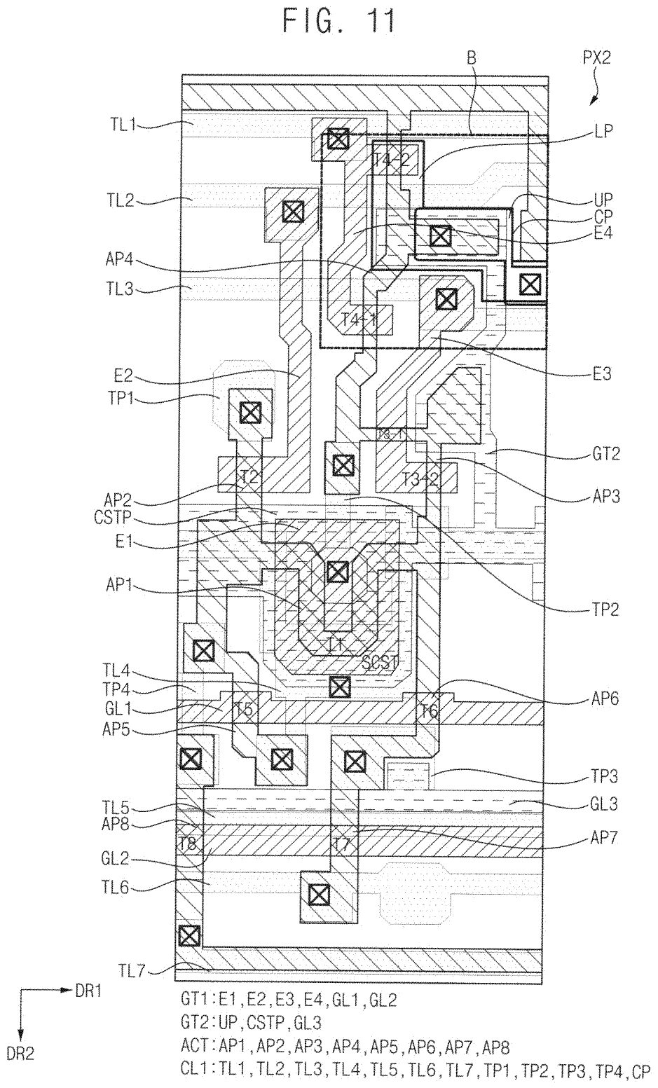

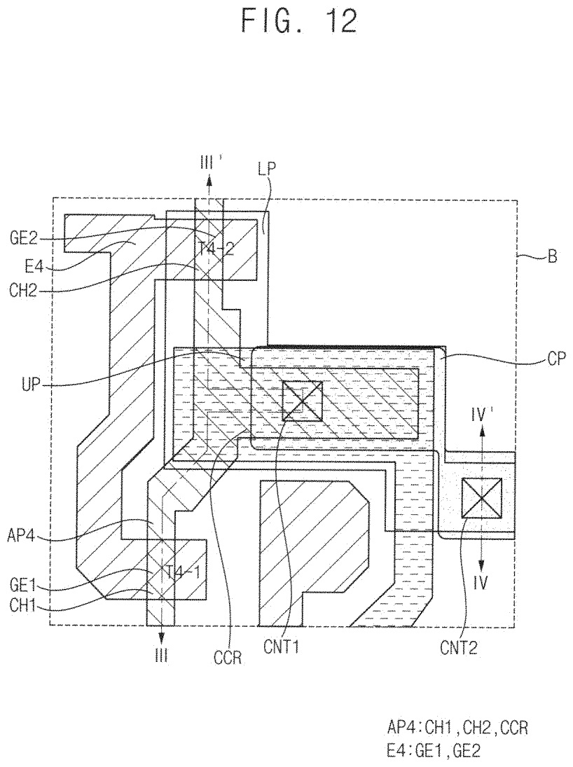

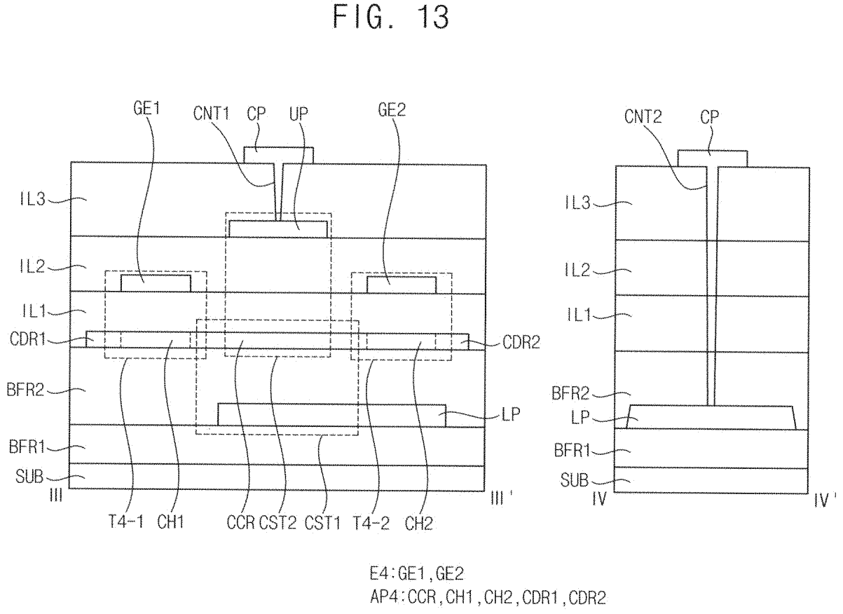

FIG. 11 is a plan view showing an alternative embodiment corresponding to FIG. 6. FIG. 12 is an enlarged plan view of area B of FIG. 11. FIG. 13 is a cross-sectional view taken along lines III-III′ and IV-IV′ of FIG. 12.

FIGS. 11 to 13 may be plan views of the pixel PX′ described above with reference to FIG. 3. Therefore, any repetitive detailed description of the same or like elements of the pixel PX2 of FIGS. 11 to 13 as those described above may be omitted or simplified.

Referring to FIGS. 7, 8, 11, 12, and 13, the fourth transistor T4 included in the pixel PX2 may have a dual-gate structure. Accordingly, the fourth active pattern AP4 included in the fourth transistor T4 may include a first conductive region CDR1, a second conductive region CDR2, a first channel region CH1, and a second channel region CH2, and a common conductive region CCR. The first conductive region CDR1 and the second conductive region CDR2 may be spaced apart from each other. The first channel region CH1 and the second channel region CH2 may be positioned between the first conductive region CDR1 and the second conductive region CDR2. The common conductive region CCR may be positioned between the first channel region CH1 and the second channel region CH2.

The fourth transistor T4 may include a first sub-transistor T4-1 and a second sub-transistor T4-2. The first sub-transistor T4-1 of the fourth transistor T4 may include the first channel region CH1 and a first gate electrode GE1. The first gate electrode GE1 may be defined by a portion of the fourth electrode E4 which overlaps the first channel region CH1. The second sub-transistor T4-2 of the fourth transistor T4 may include the second channel region CH2 and a second gate electrode GE2. The second gate electrode GE2 may be defined by another portion of the fourth electrode E4 which overlaps the second channel region CH2.

The first gate electrode GE1 and the second gate electrode GE2 may constitute the fourth electrode E4, and thus the first sub-transistor T4-1 and the second sub-transistor T4 of the fourth transistor T4 may be connected to each other.

The lower pattern LP may overlap the common conductive region CCR and the second channel region CH2 of the fourth active pattern AP4. The lower pattern LP may be spaced apart from the first channel region CH1 of the fourth active pattern AP4 in the plan view. The upper pattern UP may overlap the common conductive region CCR of the fourth active pattern AP4. The upper pattern UP may be spaced apart from the first channel region CH1 and the second channel region CH2 of the fourth active pattern AP4 in the plan view.

The lower pattern LP may constitute the common conductive region CCR and the first capacitor CST1 of the fourth active pattern AP4. The upper pattern UP may constitute the common conductive region CCR and the second capacitor CST2 of the fourth active pattern AP4.

The connection pattern CP may be connected to the lower pattern LP and the upper pattern UP on the lower pattern LP and the upper pattern UP. The lower pattern LP and the upper pattern UP may be connected to the power line PL through the connection pattern CP. Accordingly, the first capacitor CST1 and the second capacitor CST2 may receive the first voltage ELVDD through the connection pattern CP.

The first active pattern AP1 may be connected to the fourth active pattern AP4 and extend from the first channel region CH1 and the second channel region CH2 of the fourth active pattern AP4. The first active pattern AP1 may be adjacent to the first channel region CH1 and may be spaced apart from the second channel region CH2. The first transistor T1 may be disposed relatively adjacent to the first sub-transistor T4-1 of the fourth transistor T4 than the second sub-transistor T4-2 of the fourth transistor T4.

In an embodiment, the first channel region CH1 of the fourth active pattern AP4 may be connected to the first electrode E1. In an embodiment, the active layer ACT between the first channel region CH1 of the fourth active pattern AP4 and the third active pattern AP3 may be connected to the first electrode E1 through the second transmission pattern TP2. Accordingly, the first sub-transistor T4-1 of the fourth transistor T4 may be disposed relatively adjacent to the storage capacitor SCST.

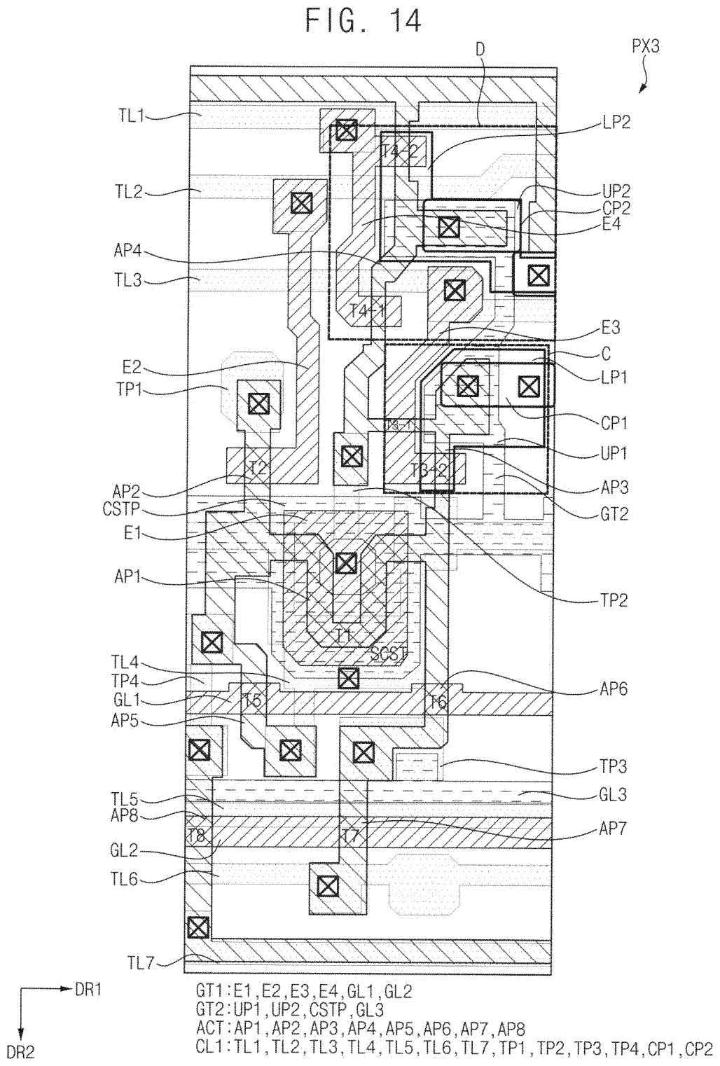

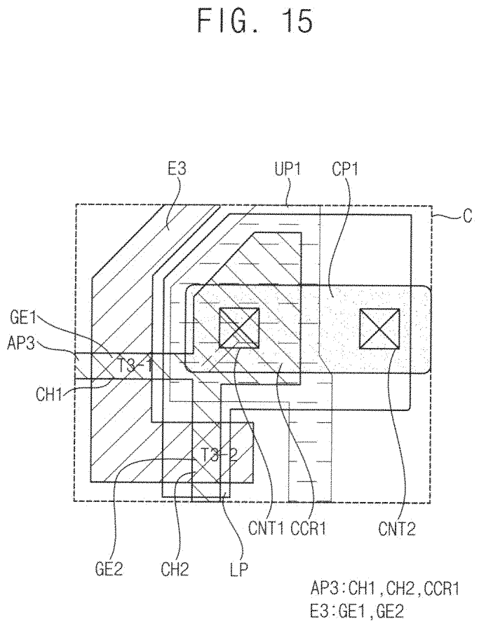

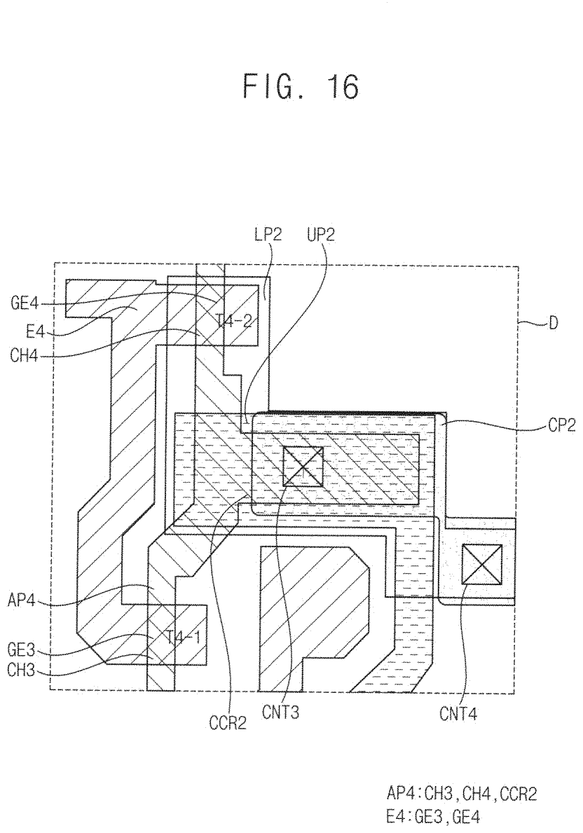

FIG. 14 is a plan view showing another alternative embodiment corresponding to FIG. 6. FIG. 15 is an enlarged view of area C of FIG. 14. FIG. 16 is an enlarged view of area D of FIG. 14.

FIGS. 14 to 16 may be plan views of the pixel PX″ described above with reference to FIG. 4. Hereinafter, any repetitive detailed description of the same or like elements of the pixel PX3 shown in FIGS. 14 to 16 as those of the pixel PX1 or PX2 described above with reference to FIGS. 5 to 13 may be omitted or simplified.

Referring to FIGS. 7, 8, 12, 13, and 14, each of the third transistor T3 and the fourth transistor T4 included in the pixel PX3 may have a dual-gate structure.

The third active pattern AP3 included in the third transistor T3 may include a first channel region CH1, a second channel region CH2, and a first common conductive region CCR1. The first channel region CH1 and the second channel region CH2 may be spaced apart from each other. The first common conductive region CCR1 may be positioned between the first channel region CH1 and the second channel region CH2.

The fourth active pattern AP4 included in the fourth transistor T4 may include a third channel region CH3, a fourth channel region CH4, and a second common conductive region CCR2. The third channel region CH3 and the fourth channel region CH4 may be spaced apart from each other. The second common conductive region CCR2 may be positioned between the third channel region CH3 and the fourth channel region CH4.

The third transistor T3 may include a first sub-transistor T3-1 and a second sub-transistor T3-2. The first sub-transistor T3-1 of the third transistor T3 may include the first channel region CH1 and a first gate electrode GE1. The first gate electrode GE1 may be defined by a portion of the third electrode E3 which overlaps the first channel region CH1. The second sub-transistor T3-2 of the third transistor T3 may include the second channel region CH2 and a second gate electrode GE2. The second gate electrode GE2 may be defined by another portion of the third electrode E3 which overlaps the second channel region CH2.

The first gate electrode GE1 and the second gate electrode GE2 may constitute the third electrode E3, and thus the first sub-transistor T3-1 and the second sub-transistor T3-2 of the third transistor T3 may be connected to each other.

The fourth transistor T4 may include a first sub-transistor T4-1 and a second sub-transistor T4-2. The first sub-transistor T4-1 of the fourth transistor T4 may include the third channel region CH3 and a third gate electrode GE3. The third gate electrode GE3 may be defined by a portion of the fourth electrode E4 which overlaps the third channel region CH3. The second sub-transistor T4-2 of the fourth transistor T4 may include the fourth channel region CH4 and a fourth gate electrode GE4. The fourth gate electrode GE4 may be defined by another portion of the fourth electrode E4 which overlaps the fourth channel region CH4.

The first gate electrode GE1 and the second gate electrode GE2 may constitute the fourth electrode E4, and thus the first sub-transistor T4-1 and the second sub-transistor T4 of the fourth transistor T4 may be connected to each other.

The first lower pattern LP1 and the second lower pattern LP2 may be disposed under the active layer ACT and may be spaced apart from each other. The first upper pattern UP1 and the second upper pattern UP2 may be included in the second gate layer GT2 and may be connected to each other.

The first lower pattern LP1 may overlap the first common conductive region CCR1 and the second channel region CH2 of the third active pattern AP3. The first lower pattern LP1 may be spaced apart from the first channel region CH1 of the third active pattern AP3 in the plan view. The first upper pattern UP1 may overlap the first common conductive region CCR1 of the third active pattern AP3. The first upper pattern UP1 may be spaced apart from the first channel region CH1 and the second channel region CH2 in the plan view.

The first lower pattern LP1 may constitute the first common conductive region CCR1 and the first capacitor CST1 of the third active pattern AP3. The first upper pattern UP1 may constitute the first common conductive region CCR1 and the second capacitor CST2 of the third active pattern AP3.

The second lower pattern LP2 may overlap the second common conductive region CCR2 and the fourth channel region CH4 of the fourth active pattern AP4. The second lower pattern LP2 may be spaced apart from the third channel region CH3 of the fourth active pattern AP4 in the plan view. The second upper pattern UP2 may overlap the second common conductive region CCR2 of the fourth active pattern AP4. The second upper pattern UP2 may be spaced apart from the third channel region CH3 and the fourth channel region CH4 of the fourth active pattern AP4 in the plan view.

The second lower pattern LP2 may constitute the second common conductive region CCR2 and the third capacitor CST3 of the fourth active pattern AP4. The second upper pattern UP2 may constitute the second common conductive region CCR2 and the fourth capacitor CST4 of the fourth active pattern AP4.

The first conductive layer CL1 disposed on the second gate layer GT2 may include a first connection pattern CP1 and a second connection pattern CP2.

The first connection pattern CP1 may be connected to the first lower pattern LP1 and the first upper pattern UP1 on the first lower pattern LP1 and the first upper pattern UP1. The first lower pattern LP1 and the first upper pattern UP1 may be connected to the power line PL through the first connection pattern CP1. Accordingly, the first capacitor CST1 and the second capacitor CST2 may receive the first voltage ELVDD through the first connection pattern CP1.

The second connection pattern CP2 may be connected to the second lower pattern LP2 and the second upper pattern UP2 on the second lower pattern LP2 and the second upper pattern UP2. The second lower pattern LP2 and the second upper pattern UP2 may be connected to the power line PL through the second connection pattern CP2. Accordingly, the third capacitor CST3 and the fourth capacitor CST4 may receive the first voltage ELVDD through the second connection pattern CP2.

The first active pattern AP1 may be connected to the third active pattern AP3 and the fourth active pattern AP4.

The first active pattern AP1 may be adjacent to the second channel region CH2 of the third active pattern AP3 and be spaced apart from the first channel region CH1 of the third active pattern AP3. The first transistor T1 may be disposed relatively adjacent to the second sub-transistor T3-2 of the third transistor T3 than the first sub-transistor T3-1 of the third transistor T3.

The first active pattern AP1 may be adjacent to the third channel region CH3 of the fourth active pattern AP4 and may be spaced apart from the fourth channel region CH4 of the fourth active pattern AP4. The first transistor T1 may be disposed relatively adjacent to the first sub-transistor T4-1 of the fourth transistor T4 than the second sub-transistor T4-2 of the fourth transistor T4.

In an embodiment, the first channel region CH1 of the third active pattern AP3 may be connected to the first electrode E1 included in the first transistor T1. The third channel region CH3 of the fourth active pattern AP4 may be connected to the first electrode E1. In an embodiment, the active layer ACT between the first channel region CH1 of the third active pattern AP3 and the third channel region CH3 of the fourth active pattern AP4 may be connected to the first electrode E1 through the second transmission pattern TP2. Accordingly, the first sub-transistor T3-1 of the third transistor T3 and the first sub-transistor T4-1 of the fourth transistor T4 may be disposed relatively adjacent to the storage capacitor SCST.

The display devices according to the embodiments may be applied to a display device included in a computer, a notebook, a mobile phone, a smartphone, a smart pad, a personal media player (PMP), a personal digital assistance (PDA), an MP3 player, or the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a light emitting diode;
a first transistor which transmits a driving current to the light emitting diode;
at least one switching transistor connected to the first transistor, wherein the at least one switching transistor includes a first sub-transistor and a second sub-transistor connected to each other through a common node; and
a back-gate terminal connected to a first power supply and the common node, wherein the back-terminal overlaps the second sub-transistor.

2. The display device of claim 1, further comprising:
a first capacitor connected to the common node and the back-gate terminal; and
a second capacitor connected to the first power supply and the common node.

3. The display device of claim 1, further comprising:
a storage capacitor connected to the first power supply and the first transistor.

4. The display device of claim 3, wherein the at least one switching transistor further includes:
a second transistor connected to a source terminal of the first transistor;
a third transistor connected to a drain terminal of the first transistor; and
a fourth transistor connected to a gate terminal of the first transistor.

5. The display device of claim 4, wherein the third transistor is connected to the fourth transistor.

6. The display device of claim 4, wherein
the third transistor is defined by the common node, the first sub-transistor, and the second sub-transistor,
the first sub-transistor is connected to the common node and the storage capacitor, and
the second sub-transistor overlaps the back-gate terminal and is connected to the common node and the first transistor.

7. The display device of claim 4, wherein
the fourth transistor is defined by the common node, the first sub-transistor, and the second sub-transistor,
the first sub-transistor is connected to the common node and the storage capacitor, and
the second sub-transistor overlaps the back-gate terminal and is connected to the common node and an initialization voltage.

8. A display device comprising:
a substrate;
a first transistor disposed on the substrate;
a light emitting diode disposed on the first transistor, and connected to the first transistor;
at least one switching transistor disposed on the substrate, wherein the at least one switching transistor includes an active layer including a first conductive area, a second conductive area, a first channel area, a second channel area and a common conductive area, wherein the first conductive area and the second conductive area are spaced apart from each other, the first channel area and the second channel area are positioned between the first conductive area and the second conductive area, and the common conductive area are positioned between the first channel area and the second channel area; and
a lower pattern disposed under the active layer and overlapping the common conductive area and the second channel area.

9. The display device of claim 8, wherein the lower pattern is spaced apart from the first channel area in a plan view.

10. The display device of claim 8, wherein the at least one switching transistor includes a first sub-transistor and a second sub-transistor which are connected to each other.

11. The display device of claim 10, wherein the first sub-transistor includes the first channel area and a first gate electrode overlapping the first channel area.

12. The display device of claim 10, wherein the second sub-transistor includes the second channel area and a second gate electrode overlapping the second channel area.

13. The display device of claim 8, further comprising:
an upper pattern disposed on the active layer, overlapping the common conductive area, and spaced apart from the first channel area and the second channel area in a plan view.

14. The display device of claim 13, wherein
the lower pattern defines a first capacitor with the common conductive area, and
the upper pattern defines a second capacitor with the common conductive area.

15. The display device of claim 13, further comprising:
a power supply line disposed on the at least one switching transistor.

16. The display device of claim 15, wherein the power supply line is connected to the lower pattern and the upper pattern.

17. The display device of claim 13, wherein
the active layer further includes an active pattern extending from the first channel area and the second channel area, and
the first transistor includes the active pattern and a first electrode disposed on the active pattern and overlapping the active pattern.

18. The display device of claim 17, wherein the at least one switching transistor includes at least one selected from a second transistor, a third transistor, and a fourth transistor, and
wherein the second transistor includes a second electrode spaced apart from the first electrode,
the third transistor includes a third electrode spaced apart from the first electrode and the second electrode, and
the fourth transistor includes a fourth electrode spaced apart from the first electrode, the second electrode, and the third electrode.

19. The display device of claim 18, wherein
the third transistor is defined by the first channel area, the second channel area, and the common conductive area, and
the first electrode is connected to the first channel area.

20. The display device of claim 18, wherein
the fourth transistor is defined by the first channel area, the second channel area, and the common conductive area, and
the first electrode is connected to the first channel area.
